(19) United States
(12) Patent Application Publication
(10) Pub. No.: US 2026/0040557 A1
(43) Pub. Date: Feb. 5, 2026

(54) SEMICONDUCTOR DEVICE AND MANUFACTURING METHOD

(71) Applicant: SK hynix Inc., Icheon-si, Gyeonggi-do (KR)

(72) Inventors: Hwan Young KIM, Icheon-si (KR); Won Tae KOO, Icheon-si (KR)

(73) Assignee: SK hynix Inc., Icheon-si, Gyeonggi-do (KR)

(21) Appl. No.: 18/917,855

(22) Filed: Oct. 16, 2024

(30) Foreign Application Priority Data
Aug. 5, 2024 (KR) 10-2024-0103739

(51) Int. Cl. H10B 43/30; H10B 43/27

(52) U.S. Cl. CPC H10B 43/30; H10B 43/27

(57) ABSTRACT

A semiconductor device may include a tunneling layer, a charge storage structure positioned on the tunneling layer, and including a plurality of first charge storage layers and a plurality of second charge storage layers that are alternately stacked, a blocking layer positioned on the charge storage structure, and an electrode layer positioned on the blocking layer.

### CROSS-REFERENCE TO RELATED APPLICATION

This application claims priority under 35 U.S.C. § 119 to Korean Patent Application No. 10-2024-0103739, filed on Aug. 5, 2024 in the Korean Intellectual Property Office, which is incorporated herein by reference in its entirety.

### BACKGROUND

### 1. Technical Field

The present disclosure relates to a charge device and a method of manufacturing the charge device, and more particularly, to a semiconductor device and a method of manufacturing the semiconductor device.

### 2. Related Art

An integration degree of a semiconductor device is mainly determined by an area occupied by a unit memory cell. Recently, as improvement in an integration degree of a semiconductor device in which a memory cell is formed as a single layer on a substrate reaches its limit, a three-dimensional semiconductor device in which memory cells are stacked on a substrate is being proposed. In addition, various structures and manufacturing methods are being developed in order to improve operation reliability of the semiconductor devices.

### SUMMARY

According to an embodiment of the present disclosure, a semiconductor device may include a tunneling layer, a charge storage structure disposed on the tunneling layer, and including a plurality of first charge storage layers and a plurality of second charge storage layers that are alternately stacked, a blocking layer disposed on the charge storage structure, and an electrode layer disposed on the blocking layer.

According to an embodiment of the present disclosure, a semiconductor device may include a gate structure including insulating layers and conductive layers alternately stacked, a channel layer extending through the gate structure, a tunneling layer surrounding the channel layer, a charge storage structure surrounding the tunneling layer, and including a plurality of first charge storage layers and a plurality of second charge storage layers alternately stacked, and a blocking layer surrounding the charge storage structure.

According to an embodiment of the present disclosure, a method of manufacturing a semiconductor device may include forming a tunneling layer, forming a charge storage structure by alternately stacking a plurality of first charge storage layers and a plurality of second charge storage layers repeatedly on the tunneling layer, forming a blocking layer on the charge storage structure, and forming an electrode layer on the blocking layer.

According to an embodiment of the present disclosure, a method of manufacturing a semiconductor device may include forming a stack by alternately stacking first material layers and second material layers, forming a channel hole extending through the stack, forming a blocking layer in the channel hole, forming a charge storage structure by alternately stacking a plurality of first charge storage layers and a plurality of second charge storage layers repeatedly on the blocking layer, forming a tunneling layer on the charge storage structure, and forming a channel layer on the tunneling layer.

### BRIEF DESCRIPTION OF THE DRAWINGS

FIG. 1 is a diagram illustrating a semiconductor device according to an embodiment of the present disclosure.

FIGS. 2A and 2B are diagrams illustrating a semiconductor device according to an embodiment of the present disclosure.

FIGS. 3A to 3C are diagrams illustrating an effect of a semiconductor device according to an embodiment of the present disclosure.

FIG. 4 is a diagram illustrating a method of manufacturing a semiconductor device according to an embodiment of the present disclosure.

FIGS. 5A and 5B are diagrams illustrating a method of manufacturing a semiconductor device according to an embodiment of the present disclosure.

### DETAILED DESCRIPTION

Embodiments of the present disclosure provide a semiconductor device and a method of manufacturing the semiconductor device having a stable structure and improved characteristics.

According to the present technology, a semiconductor device having a stable structure and improved reliability may be provided.

Hereinafter, embodiments according to the technical spirit of the present disclosure are described with reference to the accompanying drawings.

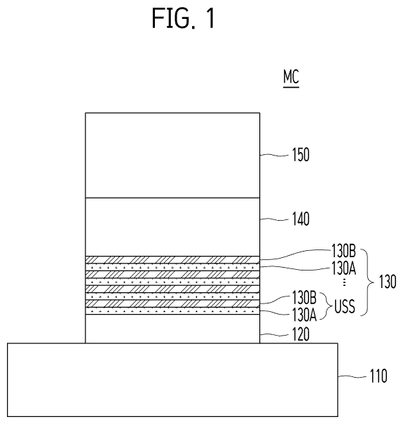

FIG. 1 is a diagram illustrating a semiconductor device according to an embodiment of the present disclosure.

Referring to FIG. 1, a semiconductor device may include a memory cell MC. The memory cell MC may include a substrate 110, a tunneling layer 120, a charge storage structure 130, a blocking layer 140, and an electrode layer 150.

The substrate 110 may include a semiconductor substrate such as a silicon substrate. The substrate 110 may include a conductive area, for example, a channel and a well doped with an impurity or a structure doped with an impurity.

The tunneling layer 120 may be positioned on the substrate 110. The tunneling layer 120 may be positioned between the substrate 110 and the charge storage structure 130. The tunneling layer 120 may be used as a path through which charges in the substrate 110 tunnel to the charge storage structure 130 when a bias is applied to the memory cell MC. The tunneling layer 120 may include an oxide. For example, the tunneling layer 120 may include SiO₂.

The charge storage structure 130 may be positioned on the tunneling layer 120. The charge storage structure 130 may include a first charge storage layer 130A and a second charge storage layer 130B.

In an embodiment, the charge storage structure 130 may include a plurality of first charge storage layers 130A and a plurality of second charge storage layers 130B alternately stacked on the tunneling layer 120. Here, one first charge storage layer 130A and one second charge storage layer 130B configuring the charge storage structure 130 may be defined as a unit storage structure USS. The charge storage structure 130 may include a plurality of unit storage structures USS stacked on the tunneling layer 120. A unit storage structure USS may have a thickness of 1 to 20 nm.

Charge may be trapped in the first charge storage layer 130A, and data may be stored in a bit form. For example, a state in which charge is retained in the first charge storage layer 130A or the charge is released from the first charge storage layer 130A may be stored as data of a bit form of ‘0’, ‘1’, or a combination thereof. The first charge storage layer 130A may include an antiferroelectric material. For example, the first charge storage layer 130A may include at least one of HfO₂ including Si (hereinafter, HfO2:Si), HfZrOx, and ZrO₂.

Charge may be trapped in the second charge storage layer 130B, and data may be stored in a bit form. For example, a state in which charge is retained in the second charge storage layer 130B or the charge is released from the second charge storage layer 130B may be stored as data in a bit form of ‘0’, ‘1’, or a combination thereof. In an embodiment, the second charge storage layer 130B may have substantially the same thickness as the first charge storage layer 130A. The second charge storage layer 130B may include a material different from that of the first charge storage layer 130A. For example, the second charge storage layer 130B may include a dielectric material. The second charge storage layer 130B may include a nitride. For example, the second charge storage layer 130B may include Si₃N₄.

A state in which charge is trapped in the first charge storage layer 130A and the second charge storage layer 130B may be referred to as a program state, and a state in which charge in the first charge storage layer 130A and/or the second charge storage layer 130B is released may be referred to as an erase state. A multi-level memory cell may be configured by changing bias applied to the memory cell MC in the form of a plurality of voltage levels to store data of a multi-bit in the first charge storage layer 130A and the second charge storage layer 130B. For example, when the memory cell MC has four states and may store data of two bits per memory cell MC, data of ‘11’ may be stored by applying a first voltage level corresponding to a first state to the memory cell MC, data of ‘01’ may be stored by applying a second voltage level corresponding to a second state to the memory cell MC, data of ‘10’ may be stored by applying a third voltage level corresponding to a third state to the memory cell MC, and data of ‘00’ may be stored by applying a fourth voltage level corresponding to a fourth state to the memory cell MC. However, the bit form is not limited to ‘11, 01, 10, and 00’. In other embodiments for example, the memory cell MC may have four or more states and may have a form of two or more bits per memory cell MC.

In a case where the charge storage layer includes an antiferroelectric material, a switching speed, a program speed, and an erase speed of the memory cell may be improved compared to a case in which the charge storage layer includes a dielectric material. When the charge storage layer includes an antiferroelectric material and a bias is applied to the memory cell, an electric field may be concentrated at an interface of the tunneling layer and the charge storage layer, and the switching speed and the operation speed of the memory cell may be improved. However, an amount of charge trapped in the charge storage layer may not be sufficient to implement a multi-level memory cell. In other words, because the amount of charge trapped in the memory cell is insufficient, distinguishing states required for implementing a multi-level memory cell MC may not be possible.

When the charge storage layer includes a dielectric material, the amount of charge trapped in the charge storage layer may be secured in the necessary amounts. When the charge storage layer includes a dielectric material, the switching speed and the operation speed of the memory cell may be relatively slow compared to a case where the charge storage layer includes an antiferroelectric material.

According to an embodiment of the present disclosure, the memory cell MC may include both of a first charge storage layer 130A including an antiferroelectric material and a second charge storage layer 130B including a dielectric material. In other words, as the first charge storage layer 130A includes an antiferroelectric material, the switching speed and the operation speed of the memory cell MC may be improved, and as the second charge storage layer 130B includes a dielectric material, because the amount of charge trapped in the memory cell MC may be sufficiently secured to implement a multi-level memory cell. Therefore, according to an embodiment of the present disclosure, the switching speed and the operation speed of the memory cell MC may be improved, and as the amount of charge trapped in the memory cell MC may be sufficiently secured, an improved multi-level memory cell may be implemented. In addition, as the improved multi-level memory cell is implemented, because an energy state that may represent an operation may be variously implemented, an improved computing-in-memory (CIM) may be implemented.

In addition, according to an embodiment of the present disclosure, the charge storage structure 130 may include the plurality of unit storage structures USS, and the charge storage structure 130 may be configured by repeatedly stacking unit storage structures USS. Here, the first charge storage layer 130A may include an antiferroelectric material, and the second charge storage layer 130B may include a dielectric material.

In addition, the first charge storage layer 130A and/or the second charge storage layer 130B may be thin with a small thickness. The unit storage structure USS including one first charge storage layer 130A and one second charge storage layer 130B may be formed in a thickness of 1 to 20 nm. When the first charge storage layer 130A is too thick, an electric field may be concentrated inside the first charge storage layer 130A rather than on a surface of the first charge storage layer 130A, and thus the switching speed and the operation speed of the memory cell MC may be reduced. When the second charge storage layer 130B is too thick, the second charge storage layer 130B may adversely affect the switching speed and the operation speed of the memory cell MC that may be improved by a thin first charge storage layer 130A. Therefore, by configuring the unit storage structure USS by controlling a thickness of the first charge storage layer 130A and the second charge storage layer 130B together, the switching speed and the operation speed of the memory cell MC may be improved, and an improved multi-level memory cell may be implemented by sufficiently securing an amount of charge trapped in the memory cell MC.

In addition, when the first charge storage layer 130A and the second charge storage layer 130B are thin, the energy required for charge to be trapped in the first charge storage layer 130A and/or the second charge storage layer 130B may be reduced. By reducing the energy required for the memory cell MC to operate, the memory cell MC may deteriorate more slowly.

In addition, the unit storage structures USS may serve to prevent or reduce a charge from tunneling at an interface between different unit storage structures USS. For example, before charges trapped in a unit storage structure USS enter an equilibrium state, the charges may be prevented from tunneling to another unit storage structure USS to improve operational reliability of the memory cell MC.

The blocking layer 140 may be positioned on the charge storage structure 130. For example, the blocking layer 140 may be positioned on the second charge storage layer 130B. The blocking layer 140 may block movement of a charge between the charge storage structure 130 and the electrode layer 150. The blocking layer 140 may include a high dielectric constant material. For example, the blocking layer 140 may include Al₂O₃.

The electrode layer 150 may be positioned on the blocking layer 140. The electrode layer 150 may include a conductive material. The electrode layer 150 may include a metal nitride. For example, the electrode layer 150 may include TiN or the like.

For reference, although not illustrated in FIG. 1, a semiconductor device may further include first conductive lines and second conductive lines positioned on the first conductive lines. Here, the first conductive lines may extend in a first direction, and the second conductive lines may extend in a second direction intersecting the first direction. The memory cells MC may be positioned in an area where the first conductive lines and the second conductive lines intersect. For example, memory cells MC may be positioned between the first conductive line and the second conductive line, and the memory cells MC may be arranged to be connected in parallel in a horizontal direction. As another example, stacked memory cells MC may be positioned between the first conductive line and the second conductive line, and the memory cells MC may be arranged to be connected in series in a vertical direction.

According to the structure described above, a memory cell MC may include a first charge storage layer 130A including an antiferroelectric material and a second charge storage layer 130B including a dielectric material. Therefore, the switching speed and the operation speed of the memory cell MC may be improved, and an improved multi-level memory cell may be implemented with enough charge trapped in the memory cell MC.

In addition, the thickness of the first charge storage layer 130A and the second charge storage layer 130B configuring the charge storage structure 130 may be relatively small. As a result, the energy required for the charge to be trapped in the first charge storage layer 130A or the second charge storage layer 130B may be reduced, and the rate or speed of deterioration of the memory cell MC may be reduced.

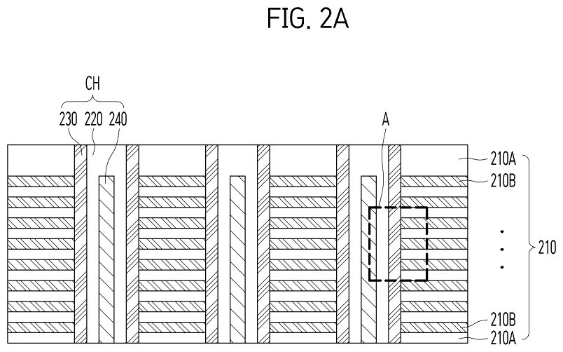

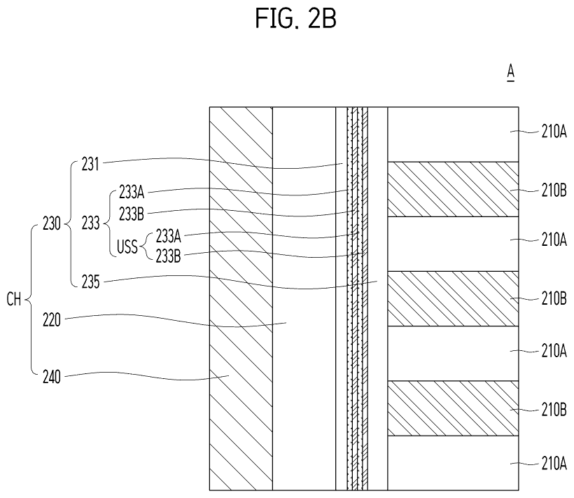

FIGS. 2A and 2B are diagrams illustrating a semiconductor device according to an embodiment of the present disclosure. FIG. 2A may be a cross-sectional view, and FIG. 2B may be an enlarged view of an area A in FIG. 2A. Hereinafter, content that overlaps with content previously described above is omitted for clarity.

Referring to FIGS. 2A and 2B, a semiconductor device may include a gate structure 210 and a channel structure CH.

The gate structure 210 may include alternately stacked insulating layers 210A and conductive layers 210B. The insulating layers 210A may include an insulating material such as an oxide, and the conductive layers 210B may include a conductive material such as tungsten, molybdenum, or polysilicon. The conductive layers 210B may be a gate line such as a source selection line, a word line, or a drain selection line. A source selection transistor, a memory cell, or a drain selection transistor may be positioned in an area where the channel structures CH and the conductive layers 210B intersect. For example, at least one source selection transistor, a plurality of memory cells, and at least one drain selection transistor stacked along the channel structure CH may configure one memory string.

The channel structure CH may extend through the gate structure 210. The channel structure CH may include a channel layer 220 and a memory layer 230 surrounding the channel layer 220. The channel structure CH may further include an insulating core 240 positioned in the channel layer 220. Here, the channel layer 220 may include a semiconductor material such as polysilicon or germanium. The insulating core 240 may include an insulating material such as an oxide.

Referring to FIG. 2B, the memory layer 230 may include a tunneling layer 231, a charge storage structure 233, and a blocking layer 235. Here, the tunneling layer 231, the charge storage structure 233, and the blocking layer 235 may be sequentially layered to surround the channel layer 220.

The tunneling layer 231 may surround the channel layer 220. The tunneling layer 231 may be positioned between the channel layer 220 and the charge storage structure 233. The tunneling layer 231 may be used as a path through which a charge in the channel layer 220 tunnels to the charge storage structure 233 when a bias is applied to the conductive layers 210B. The tunneling layer 231 may include an oxide. For example, the tunneling layer 231 may include SiO₂.

The charge storage structure 233 may surround the channel layer 220 and may include a plurality of unit storage structures USS. Here, the unit storage structure USS may include one first charge storage layer 233A and one second charge storage layer 233B alternately stacked, and the unit storage structure USS may have a thickness of 1 to 20 nm. The charge storage structure 233 may surround the channel layer 220 and may include a plurality of first charge storage layers 233A and a plurality of second charge storage layers 233B alternately and repeatedly stacked.

The first charge storage layer 233A may include an antiferroelectric material. Here, the antiferroelectric material may be at least one of HfO₂ including Si (hereinafter, HfO₂:Si), HfZrOx, and ZrO₂. The second charge storage layer 233B may include a dielectric material. Here, the dielectric material may be Si₃N₄. Charge may be trapped in the first charge storage layer 233A and the second charge storage layer 233B, and data may be stored in a bit form. The second charge storage layer 233B may have substantially the same thickness as the first charge storage layer 233A.

According to an embodiment of the present disclosure, both of the first charge storage layer 233A including an antiferroelectric material and the second charge storage layer 233B including a dielectric material may be included in the memory cell. As a result, the switching speed and the operation speed of the memory cell may be improved, and an improved multi-level memory cell may be implemented with enough charge trapped in the memory cell.

The blocking layer 235 may surround the charge storage structure 233. For example, the blocking layer 235 may be positioned between the second charge storage layer 233B and the conductive layers 210B. The blocking layer 235 may block movement of charge between the second charge storage layer 233B and the conductive layers 210B. The blocking layer 235 may include a high dielectric constant material. For example, the blocking layer 235 may include Al₂O₃.

According to the structure described above, memory cells may be positioned in an area where the channel structures CH and the conductive layers 210B intersect. Stacked memory cells may share the tunneling layer 231, the charge storage structure 233, and the blocking layer 235.

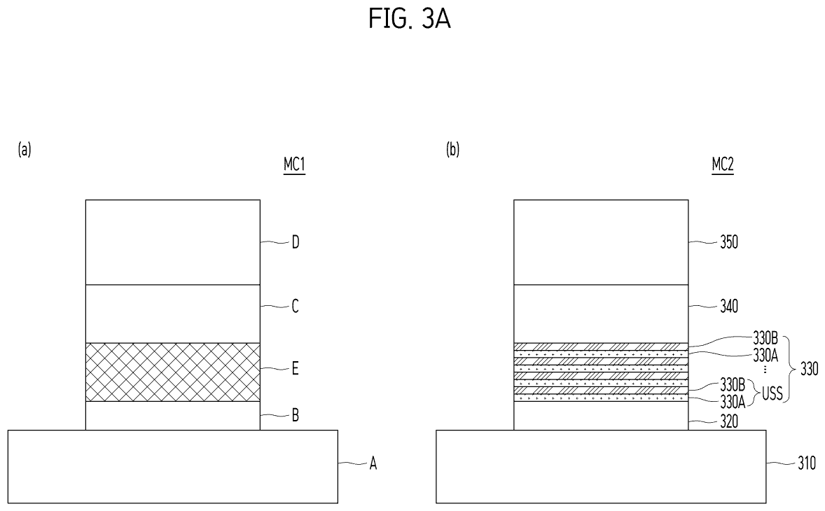

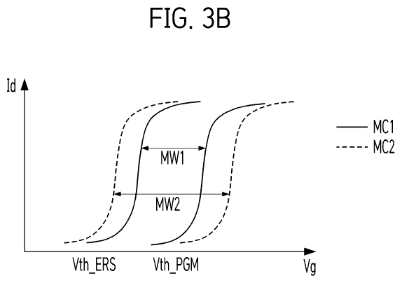

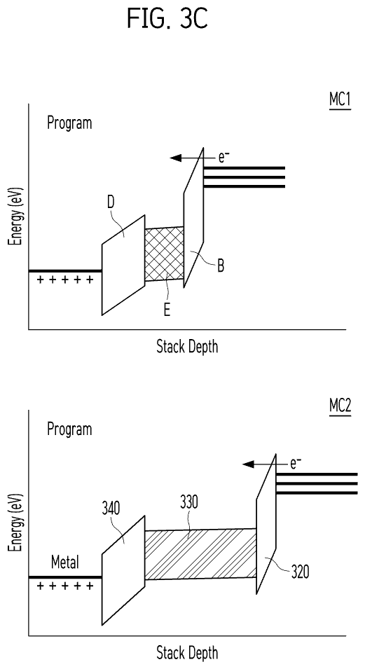

FIGS. 3A to 3C are drawings illustrating an effect of a semiconductor device according to an embodiment of the present disclosure. Hereinafter, content that overlaps with content previously described above is omitted for clarity.

Referring to (a) of FIG. 3A, a first memory cell MC1 includes a substrate A, a tunneling layer B, a third charge storage layer E, a blocking layer C, and an electrode layer D. For example, the first memory cell MC1 includes the tunneling layer B, the third charge storage layer E, the blocking layer C, and the electrode layer D that are sequentially stacked on the substrate A. Here, the third charge storage layer E includes a dielectric material.

Referring to (b) of FIG. 3A, a second memory cell MC2 includes a substrate 310, a tunneling layer 320, a charge storage structure 330, a blocking layer 340, and an electrode layer 350. For example, the second memory cell MC2 includes the tunneling layer 320, the charge storage structure 330, the blocking layer 340, and the electrode layer 350 sequentially stacked on the substrate 310. Here, the charge storage structure 330 includes a plurality of first charge storage layers 330A and a plurality of second charge storage layers 330B alternately and repeatedly stacked. In other words, the charge storage structure 330 includes a plurality of unit storage structures USS that are stacked, with each unit storage structure USS including a first charge storage layers 330A and a second charge storage layers 330B.

Referring to FIG. 3B, an x-axis means a threshold voltage, and a y-axis means a current amount. Referring to FIG. 3C, an x-axis means a stack depth of memory cells, and a y-axis means an energy size. Referring to FIGS. 3B and 3C, charge trap capacities of the first memory cell MC1 and the second memory cell MC2 may be compared.

Referring to FIG. 3B, memory windows MW of the first memory cell MC1 and the second memory cell MC2 may be compared. Here, the memory window MW may mean a difference between a threshold voltage Vth_PGM of programmed memory cells MC1 and MC2 and a threshold voltage Vth_ERS of erased memory cells MC1 and MC2, respectively. In other words, the memory window MW may mean a charge trap capacity as a total space for a level of a voltage used to implement a multi-level memory cell.

The first memory cell MC1 includes a third charge storage layer E including a dielectric material. The second memory cell MC2 includes first charge storage layers 330A with an antiferroelectric material and second charge storage layers 330B with a dielectric material. Here, in the second memory cell MC2, charge may be additionally trapped at an interface between the first charge storage layer 330A and the second charge storage layer 330B. As a result, even though the third charge storage layer E and the charge storage structure 330 have substantially the same thickness, more charge trap space and more charge trap capacity may be provided in the charge storage structure 330. Therefore, the second memory cell MC2 may have a second memory window MW2 that is greater than a first memory window MW1 of the first memory cell MC1.

Referring to (a) of FIG. 3C, when a bias is applied to the first memory cell MC1, charges may move through the tunneling layer B, the third charge storage layer E, and a blocking layer D. In this process, charge may be trapped in the third charge storage layer E.

Referring to (b) of FIG. 3C, when a bias is applied to the second memory cell MC2, charge may move through the tunneling layer 320, the charge storage structure 330, and the blocking layer 340. In this process, charge may be trapped in the charge storage structure 330. In addition, charge may be trapped at interfaces between the first charge storage layer 330A and the second charge storage layer 330B. In other words, the second memory cell MC2 may have a charge trapping capacity greater than that of the first memory cell MC1.

According to the structures described above, the second memory cell MC2 includes a first charge storage layer 330A including an antiferroelectric material and a second charge storage layer 330B including a dielectric material as a unit storage structure USS. Unit storage structures USS are alternately and repeatedly stacked to form the charge storage structure 330. Therefore, the second memory cell MC2 may secure sufficient charge trap capacity to implement a multi-level memory cell and to improve the operation speed.

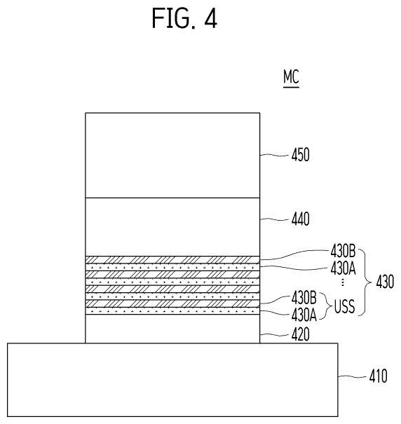

FIG. 4 is a drawing illustrating a method of manufacturing a semiconductor device according to an embodiment of the present disclosure. Hereinafter, content that overlaps with content previously described above is omitted for clarity.

Referring to FIG. 4, a tunneling layer 420 may be formed. For example, the tunneling layer 420 may be formed on a substrate 410. Here, the substrate 410 may include a semiconductor substrate such as a silicon substrate.

The tunneling layer 420 may be used as a path through which a charge in the substrate 410 tunnels to a charge storage structure 430 when a bias is applied to a memory cell. The tunneling layer 420 may include an oxide. For example, the tunneling layer 420 may include SiO₂.

Subsequently, a charge storage structure 430 may be formed on the tunneling layer 420. For example, the charge storage structure 430 may be formed by alternately stacking a plurality of first charge storage layers 430A and a plurality of second charge storage layers 430B repeatedly on the tunneling layer 420. Here, one first charge storage layer 430A and one second charge storage layer 430B may be defined as a unit storage structure USS. A unit storage structure USS may have a thickness of 1 to 20 nm. Charge may be trapped in the unit storage structure USS with the first charge storage layer 430A and the second charge storage layer 430B, and data may be stored in a bit form.

The first charge storage layer 430A may include an antiferroelectric material, and the second charge storage layer 430B may include a dielectric material. For example, the first charge storage layer 430A may include at least one of HfO₂:Si, HfZrOx, and ZrO₂, and the second charge storage layer 430B may include Si₃N₄.

In addition, the first charge storage layer 430A and/or the second charge storage layer 430B may each be very thin, and the unit storage structure USS including one first charge storage layer 430A and one second charge storage layer 430B may be only have a thickness of 1 to 20 nm. By forming the unit storage structure USS while controlling the combined thickness of the first charge storage layer 430A and the second charge storage layer 430B, the switching speed and the operation speed of the memory cell MC may be improved, and an improved multi-level memory cell may be implemented by having enough charge trapped in the memory cell MC.

In addition, when the first charge storage layer 430A and the second charge storage layer 430B are thin, the energy required to trap charge in the first charge storage layer 430A and/or the second charge storage layer 430B may be reduced. As a result, the rate of deterioration of the memory cell MC may be reduced by reducing the energy required for the memory cell MC to operate.

In addition, the unit storage structures USS may serve to prevent or reduce a charge from tunneling at an interface between adjacent unit storage structures USS. For example, before the charges trapped in the unit storage structure USS reach an equilibrium state, charges may be prevented from tunneling to another unit storage structure USS. As a result, operation reliability of the memory cell MC may be improved.

Subsequently, a blocking layer 440 may be formed on the charge storage structure 430. The blocking layer 440 may block movement of charges between the charge storage structure 430 and an electrode layer 450. The blocking layer 440 may include a high dielectric constant material. For example, the blocking layer 440 may include Al₂O₃.

Subsequently, the electrode layer 450 may be formed on the blocking layer 440. The electrode layer 450 may include a conductive material. The electrode layer 450 may include a metal nitride. For example, the electrode layer 450 may include TiN or the like. Accordingly, a memory cell MC including the substrate 410, the tunneling layer 420, the charge storage structure 430, the blocking layer 440, and the electrode layer 450 may be formed.

According to an embodiment of the present disclosure, a memory cell MC may include both of a first charge storage layer 430A including an antiferroelectric material and a second charge storage layer 430B including a dielectric material. The switching speed and the operation speed of the memory cell MC may be improved, and a multi-level memory cell may be implemented with sufficient charge trapped in the memory cell MC.

According to a manufacturing method described above, a charge storage structure 430 may be formed by alternately stacking a plurality of first charge storage layers 430A and a plurality of second charge storage layers 430B repeatedly on a tunneling layer 420. One first charge storage layers 430A and one second charge storage layers 430B are included in a unit storage structure USS. A plurality of the unit storage structures USS are stacked to form a charge storage structure 430. Each unit storage structure USS may be formed to be very thin. The first charge storage layers 430A may include an antiferroelectric material, and the second charge storage layers 430B may include a dielectric material.

The switching speed and the operation speed of memory cells MC described above may be improved, and a multi-level memory cell may be implemented by securing a sufficient amount of charge trapped in the memory cell MC. Using very thin unit storage structures USS with charge trapped in the first charge storage layer 430A and/or the second charge storage layer 430B, the energy required for operations may be reduced, and the memory cells MC may deteriorate more slowly.

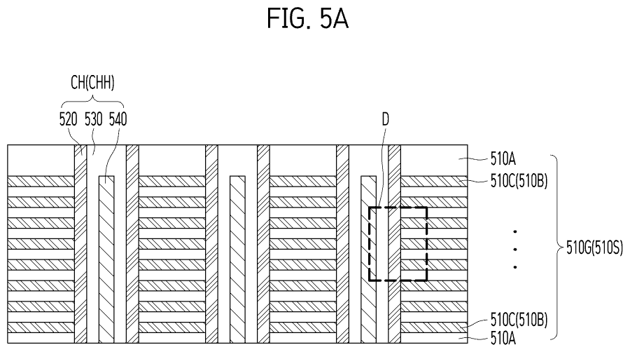

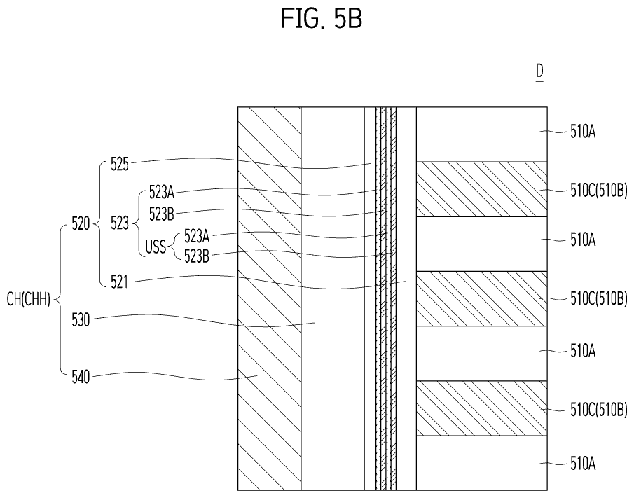

FIGS. 5A to 5B are diagrams illustrating a method of manufacturing a semiconductor device according to an embodiment of the present disclosure. FIG. 5A may be a cross-sectional view, and FIG. 5B may be an enlarged view of area B of FIG. 5A. Hereinafter, content that overlaps with content previously described above is omitted for clarity.

Referring to FIGS. 5A and 5B, a stack 510S may be formed by alternately stacking first material layers 510A and second material layers 510B. The first material layers 510A may include an insulating material such as an oxide, and the second material layers 510B may include a sacrificial material such as a nitride.

Subsequently, a channel hole CHH extending through the stack 510S may be formed. Subsequently, a blocking layer 521 may be formed in the channel hole CHH. The blocking layer 521 may block movement of a charge between a charge storage structure 523 and third material layers 510C. The blocking layer 521 may include a high dielectric constant material. For example, the blocking layer 521 may include Al₂O₃.

Subsequently, a charge storage structure 523 may be formed on the blocking layer 521. For example, the charge storage structure 523 may be formed by alternately stacking a plurality of first charge storage layers 523A and a plurality of second charge storage layers 523B repeatedly on the blocking layer 521. Here, a stacked first charge storage layer 523A and a second charge storage layer 523B may be defined as a unit storage structure USS. Charge may be trapped in the first charge storage layer 523A and the second charge storage layer 523B, and data may be stored in a bit form.

The first charge storage layer 523A may include an antiferroelectric material, and the second charge storage layer 523B may include a dielectric material. For example, the first charge storage layer 523A may include at least one of HfO₂:Si, HfZrOx, and ZrO₂, and the second charge storage layer 523B may include Si₃N₄.

Subsequently, a tunneling layer 525 may be formed on the charge storage structure 523. Accordingly, a memory layer 520 including the tunneling layer 525, the charge storage structure 523, and the blocking layer 521 may be formed. The tunneling layer 525 may be used as a path through which charges from a channel layer 530 tunnel to the charge storage structure 523 when a bias is applied to the third material layers 510C. The tunneling layer 525 may include an oxide. For example, the tunneling layer 525 may include SiO₂.

Subsequently, a channel layer 530 may be formed on the memory layer 520. For example, the channel layer 530 may be formed on the tunneling layer 525. Subsequently, an insulating core 540 may be formed on the channel layer 530. Accordingly, a channel structure CH including the memory layer 520, the channel layer 530, and the insulating core 540 may be formed. The channel layer 530 may include a semiconductor material such as polysilicon or germanium, and the insulating core 540 may include an insulating material such as an oxide.

Subsequently, the second material layers 510B may be replaced with third material layers 510C through a slit (not shown). For example, after removing the second material layers 510B through the slit, the third material layers 510C may be deposited. Here, the third material layers 510C may include a conductive material. Accordingly, a gate structure 510G including the first material layers 510A and the third material layers 510C alternately stacked may be formed. In other embodiments, when the second material layers 510B include a conductive material, a process of replacing the second material layers 510B with the third material layers 510C may be omitted, and the stack 510S may be used as the gate structure 510G.

According to the manufacturing methods described above, memory cells may be positioned in an area where the channel structures CH and the third material layers 510C intersect. Stacked memory cells may share a tunneling layer 525, a charge storage structure 523, and a blocking layer 521.

Although embodiments according to the technical spirit of the present disclosure have been described with reference to the accompanying drawings, this is only for describing embodiments according to the concepts of the present disclosure, and the present disclosure is not limited to the above-described embodiments. In the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A semiconductor device comprising:
a tunneling layer;
a charge storage structure disposed on the tunneling layer, and including a plurality of first charge storage layers and a plurality of second charge storage layers that are alternately stacked;
a blocking layer disposed on the charge storage structure; and
an electrode layer disposed on the blocking layer.

2. The semiconductor device according to claim 1, wherein a first charge storage layer and a second charge storage layer include different materials.

3. The semiconductor device according to claim 2, wherein the first charge storage layer includes an antiferroelectric material, and the second charge storage layer includes a dielectric material.

4. The semiconductor device according to claim 3, wherein the first charge storage layer includes at least one of HfO₂:Si, HfZrOx, and ZrO₂, and
the second charge storage layer includes Si₃N₄.

5. The semiconductor device according to claim 1, wherein the first charge storage layers and the second charge storage layers have substantially the same thickness.

6. The semiconductor device according to claim 1, wherein the charge storage structure is configured by a plurality of unit storage structures each including one first charge storage layer and one second charge storage layer.

7. The semiconductor device according to claim 6, wherein the plurality of the unit storage structures are stacked to alternate the first charge storage layers and the second charge storage layers in the charge storage structure.

8. A semiconductor device comprising:
a gate structure including insulating layers and conductive layers alternately stacked;
a channel layer extending through the gate structure;
a tunneling layer surrounding the channel layer;
a charge storage structure surrounding the tunneling layer, and including a plurality of first charge storage layers and a plurality of second charge storage layers alternately stacked; and
a blocking layer surrounding the charge storage structure.

9. The semiconductor device according to claim 8, wherein a first charge storage layer and a second charge storage layer include different materials.

10. The semiconductor device according to claim 9, wherein the first charge storage layer includes an antiferroelectric material, and
the second charge storage layer includes a dielectric material.

11. The semiconductor device according to claim 10, wherein the first charge storage layer includes at least one of HfO₂:Si, HfZrOx, and ZrO₂, and
the second charge storage layer includes Si₃N₄.

12. The semiconductor device according to claim 8, wherein a first charge storage layer and a second charge storage layer have substantially the same thickness.

13. The semiconductor device according to claim 8, wherein the charge storage structure is configured by a plurality of unit storage structures each including one first charge storage layer and one second charge storage layer.

14. The semiconductor device according to claim 13, wherein the plurality of the unit storage structures are stacked to alternate the first charge storage layers and the second charge storage layers in the charge storage structure.
